(19) United States
(12) Patent Application Publication
(10) Pub. No.: US 2008/0298410 A1
(43) Pub. Date: Dec. 4, 2008

(54) LASER APPARATUS AND THE MANUFACTURING METHOD THEREOF

(75) Inventors: Tzu-Huan CHENG, Taipei (TW); Cheng-Ting LEE, Taipei (TW); Wen-Wei HSU, Taipei (TW); Chee-Wee LIU, Taipei (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: NATIONAL TAIWAN UNIVERSITY, Taipei (TW)

(21) Appl. No.: 11/867,514

(22) Filed: Oct. 4, 2007

(30) Foreign Application Priority Data
May 31, 2007 (TW) 096119619

(51) Int. Cl. H01S 5/00

(52) U.S. Cl. 372/45.01

(57) ABSTRACT

A laser apparatus is provided. The laser apparatus includes at least one semiconductor layer having a first surface and a second surface and an insulator layer formed on the first surface of the at least one semiconductor layer, wherein the at least one semiconductor layer and the insulator form a laser cavity.

### FIELD OF THE INVENTION

The present invention relates to a laser apparatus and the manufacturing method thereof, and more particularly to a laser apparatus with a structure of conductor-insulator-semiconductor-conductor layer, and the manufacturing method thereof.

### BACKGROUND OF THE INVENTION

Generally speaking, basic components of a computer include memories, central processing units and controllers. Although the processing speed of the mentioned components is elevated, the electrical resistance and capacitance of the wires connecting each IC chip and connecting the IC chips with the major components are increased due to the minification thereof, and hence result in delayed signals and an entirely reduced speed. It is a serious problem to be solved in the IC industry.

Nowadays, a light emitting source is usually made of III-V semiconductors additionally embedded in the silicon process. However, the costs of both the materials and the processes in the process of embedding and integrating are high.

In the prior art, the metal oxide silicon (MOS) is generally used in the process of semiconductor components. However, the feasibility of light emitting of MOS is always underestimated due to the indirect bandgap of silicon. In the Taiwan patent publication No. 00456057, the inventors, Ching-Fuh Lin and Chee-Wee Liu, first disclose a light emitting technique of MOS, where silicon emits lights unlimited by its indirect bandgap. This patent provides a light emitting diode emitting a light with a wavelength close to 1.1 μg m of the energy band of silicon by using the structures of metal oxide semiconductors, the characteristics of the energy band of silicon, and the electron-hole plasma recombination theory, which are compatible to the present process techniques of semiconductor components. After that, Lin and Liu publish the article, “Temperature dependence of the electron-hole-plasma electroluminescence from metal-oxide-silicon tunneling diodes”, in Applied Physics Letters, 2000, which discloses that the low temperature doesn't affect the efficiency of light emitting. Furthermore, they publish the article, “Roughness-enhanced electroluminescence from metal-oxide-silicon tunneling diodes”, in IEEE electron device letter (EDL), 2000, and the publication is granted with the U.S. patent (the U.S. Pat. No. 6,794,309). In 2000, they discover that the light emitting phenomenon also occurs in the base of {110}, and this discovery is published in Japanese J. of Applied Physics. Moreover, they also discover that Germanium has better quantum efficiency, which is published in Applied Physics Letters, 2006. However, the preceding studies still can not achieve a laser apparatus constructed with a conductor-insulator-semiconductor-conductor structure.

Accordingly, in view of the unachievable aims of the prior arts, the inventors provide the present invention, “Laser Apparatus and the manufacturing method thereof”, and the summary of the present invention is described as follows.

### SUMMARY OF THE INVENTION

In accordance with one aspect of the present invention, a laser apparatus generating laser lights by a MOS structure and the manufacturing method thereof are provided, which overcome the issue of the high cost of the process embedding III-V elements into silicon components.

In accordance with another aspect of the present invention, a laser apparatus is provided. The laser apparatus includes at least one semiconductor layer having a first surface and a second surface, and an insulator layer formed on the first surface of the at least one semiconductor layer, wherein the at least one semiconductor layer and the insulator form a laser cavity. In addition, the laser apparatus further includes a substrate mounted under the second surface of the at least one semiconductor layer, a first conductor layer formed on the insulator layer and a second conductor layer formed under the substrate.

Preferably, a laser emitting source is formed on the MOS structure and embedded in a general IC process.

Additional objects and advantages of the invention will be set forth in the following descriptions with reference to the accompanying drawings, in which:

### BRIEF DESCRIPTION OF THE DRAWINGS

FIG. 1A is a flowchart illustrating the manufacturing process of the laser apparatus according to a first preferred embodiment of the present invention;

FIG. 1B is a flowchart illustrating the manufacturing process of the laser apparatus according to a second preferred embodiment of the present invention;

FIG. 2A is a schematic diagram showing the regional doped semiconductor being doped in layers of the present invention;

FIG. 2B is a schematic diagram showing the regional doped semiconductor being doped with gradually varying concentrations of the present invention;

FIG. 2C is another schematic diagram showing the regional doped semiconductor being doped with gradually varying concentrations of the present invention;

FIG. 3 is a schematic diagram showing the laser apparatus emitting lights according to a third preferred embodiment of the present invention;

FIG. 4 is a broken-line graph showing the light intensity of the laser apparatus of the present invention after a current is input thereto; and

FIG. 5 is a broken-line graph showing the light characteristic of the laser apparatus of the present invention when the temperature is 300K and the input current is 800 mA.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

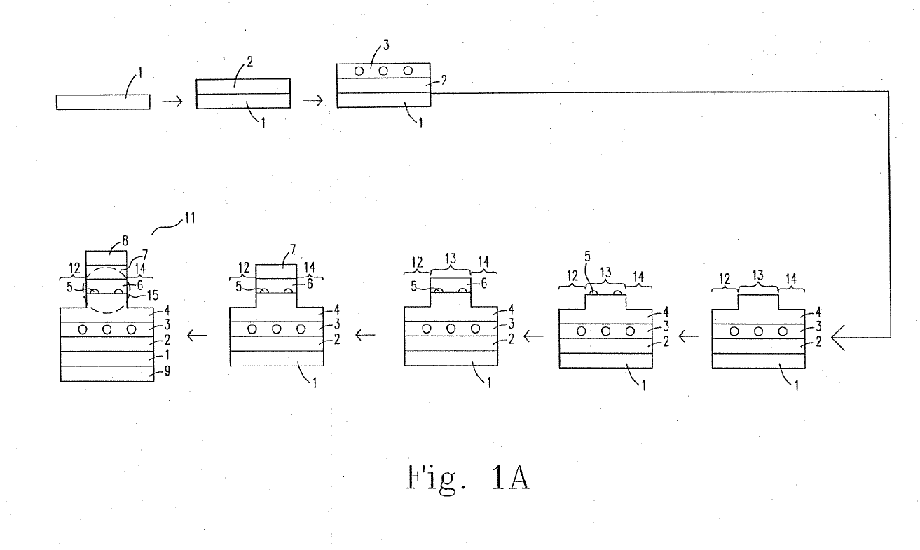

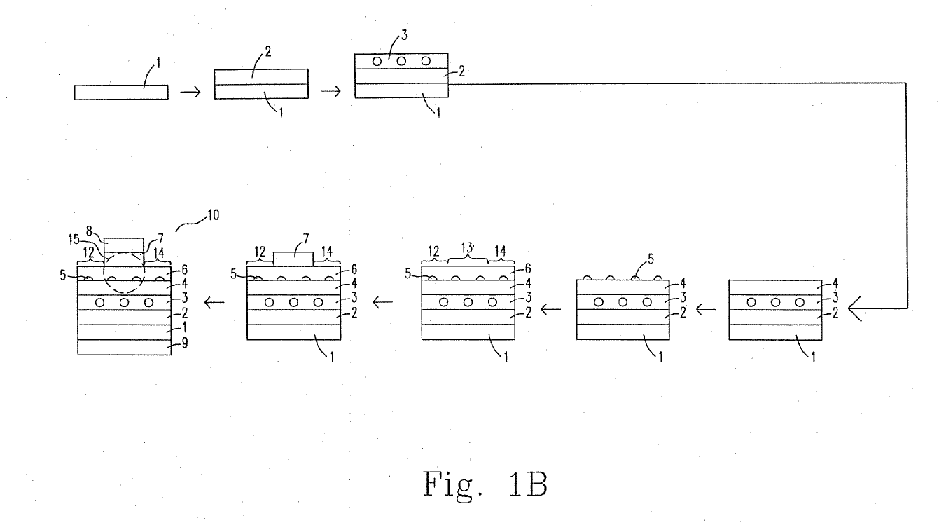

Please refer to FIG. 1A, which shows a flowchart illustrating the manufacturing process of the laser apparatus according to the first preferred embodiment of the present invention.

First of all, a substrate 1 is provided, and then a semiconductor layer 2 is formed on the substrate 1; after that, a buffer layer 3 is formed on the semiconductor layer 2.

Secondly, another semiconductor layer 4 is formed on the buffer layer 3, wherein there are three regions on the surface of the semiconductor layer 4, which are the first surface 12, the second surface 13 and the third surface 14 respectively, and the second surface 13 is configured higher than the first surface 12 and the third surface 14.

Thereafter, quantum dots 5 are formed on the second surface 13 of the semiconductor 4.

Then, another semiconductor layer 6 is formed on the second surface 13 which has the quantum dots 5.

After that, an insulator layer 7 is formed on the semiconductor layer 6.

Next, a conductor layer 8 is formed on the insulator layer 7, and another conductor layer 9 is formed under the substrate 1. A laser cavity 15 is formed by treating the insulator layer 7 and the conductor layer 9 using a combination of a lithography and etching technique, a lapping and polish technique, and a thin film coating technique. Besides, the laser cavity 15 can be formed by splitting along a crystal structure of the layers. Thus, the laser apparatus 11 of the present invention is completed.

Please refer to FIG. 1B, which shows a flowchart illustrating the manufacturing process of the laser apparatus according to the second preferred embodiment of the present invention.

First of all, a substrate 1 is provided, and then a semiconductor layer 2 is formed on the substrate 1; after that, a buffer layer 3 is formed on the semiconductor layer 2.

Secondly, another semiconductor layer 4 is formed on the buffer layer 3, wherein there are three regions on the surface of the semiconductor layer 4, which are the first surface 12, the second surface 13 and the third surface 14 respectively, and the second surface 13 is configured as high as the first surface 12 and the third surface 14.

Thereafter, quantum dots 5 are formed all over on the first surface 12, the second surface 13 and the third surface 14 of the semiconductor 4. Of course, in other preferred embodiments where the second surface 13 is configured as high as the first surface 12 and the third surface 14, the quantum dots 5 can also be formed only on the second surface 13 but not on the first surface 12 and the third surface 14.

Then, another semiconductor layer 6 is formed on the first surface 12, the second surface 13 and the third surface 14 of the semiconductor 4.

After that, an insulator layer 7 is formed on a certain area of the semiconductor layer 6, wherein the certain area is corresponding to the second surface 13.

Thereafter; a conductor layer 8 is formed on the insulator layer 7, and another conductor layer 9 is formed under the substrate 1. A laser cavity 15 is formed by treating the insulator layer 7 and the conductor layer 9 using a combination of a lithography and etching technique, a lapping and polish technique, and a thin film coating technique. Besides, the laser cavity 15 can also be formed by splitting along a crystal structure of the layers. Thus, the laser apparatus 10 of the present invention is completed.

According to the above-mentioned first and second preferred embodiments, the structure thereof is “the conductor layer 9 the substrate 1→the semiconductor layer 2→the buffer layer 3→the semiconductor layer 4→the quantum dots 5→the semiconductor layer 6→ the insulator layer 7→the conductor layer 8″ from upside to downside. However, other structures are practicable in other embodiments.

As to the conductor layer 9, the material thereof can be one selected from a group consisting of a metal, an alloy, a relative heavily doped III-V semiconductor, and any electrically conductive materials, wherein the metal can be aluminum, platinum or gold. The relative heavily doped III-V semiconductor can be one selected from a group consisting of a single crystal, a poly-crystal and a non-crystal, and also can be one of a binary compound and a multi-element compound, and further can be one of a P type semiconductor and an N type semiconductor.

In addition, the present invention can be achieved without the substrate 1. In the preferred embodiments with the substrate 1, the substrate 1 can be one selected from a group consisting of a silicon substrate, a germanium substrate, a semiconductor substrate, a crystal substrate, a glass substrate, a plastic substrate and a combination thereof, which can be made of any materials capable of bearing weight. The substrate 1 may have a crystal orientation being one selected from a group consisting of {100}, {110} and {111}. In addition, the substrate 1 can be one of a P type doped substrate and an N type doped substrate. Furthermore, the semiconductor layer 2 can be formed upon the substrate by an epitaxy technique.

The present invention can be achieved with only one semiconductor layer, or with more than one semiconductor layer, but at least one semiconductor layer is necessary. As to the material of the semiconductor layers 2, 4 and 6, they can be one selected from a group consisting of a silicon, a germanium, a IV semiconductor, a III-V semiconductor, and a II-VI semiconductor. Meanwhile, the semiconductor layers 2, 4 and 6 can be one of a single crystal and a poly-crystal, and also can be one of a P type doped semiconductor and an N type doped semiconductor.

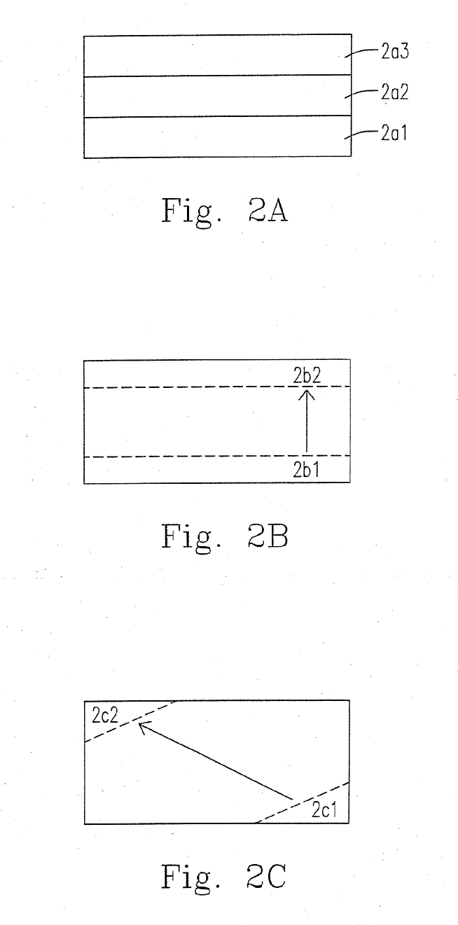

Please refer to FIG. 2A, which is a schematic diagram showing the regional doped semiconductor being doped in layers of the present invention. As described above, the semiconductor layers 2, 4 and 6 can be a P type doped semiconductor or an N type doped semiconductor, which further can be a regional doped semiconductor or other types of doped semiconductors. The regional doped semiconductor can be doped in layers as shown in FIG. 2A, which contains a first concentration layer 2a1, a second concentration layer 2a2 and a third concentration layer 2a3.

Please refer to FIG. 2B, which is a schematic diagram showing the regional doped semiconductor being doped with gradually varying concentrations of the present invention. The semiconductor layers 2, 4 and 6 can be the regional doped semiconductors being doped with gradually varying concentrations, and the gradually varying concentrations have a horizontal concentration gradient ranged from a first concentration 2b1 to a second concentration 2b2 as shown in FIG. 2B, wherein the first concentration 2b1 can be higher than the second concentration 2b2, or lower than the second concentration 2b2.

Please refer to FIG. 2C, which is another schematic diagram showing the regional doped semiconductor being doped with gradually varying concentrations of the present invention. The semiconductor layers 2, 4 and 6 can be the regional doped semiconductors being doped with gradually varying concentrations, and the gradually varying concentrations have a slanting concentration gradient ranged from a first concentration 2c1 to a second concentration 2c2 as shown in FIG. 2C, wherein the first concentration 2c1 can be higher than the second concentration 2c2, or lower than the second concentration 2c2.

The present invention can be achieved without the buffer layer 3. Moreover, the present invention can further contain a buffer layer, a stress buffering layer, a hollow layer or a combination thereof.

The present invention can be achieved without the quantum dots 5. Moreover, the present invention can further contain at least a quantum dot, at least a quantum line, at least a quantum well or a combination thereof.

As to the insulator layer 7, the material thereof can be one selected from a group consisting of a silicon oxide, an aluminum oxide, a silicon nitride, a hafnium oxide, any other insulating material and a combination thereof.

As to the laser cavity 15, it can be in a shape of one of a bar and a disk, and it also can be in any other shape with the function of optical resonance. In addition, the laser cavity 15 can be formed through splitting along a crystal structure of the layers, and thus a natural fracture surface is formed, wherein the reflections of the optical resonance occur thereon. Besides, the reflection surface of the laser cavity 15 for the optical resonance can be formed by one selected from a group consisting of a lithography and etching technique, a lapping and polish technique, a thin film coating technique, and a combination thereof.

As to the first surface 12, the second surface 13 and the third surface 14, the second surface 13 can be configured higher than the first surface 12 and the third surface 14, and also can be configured as high as the other two surfaces. The insulator layer 7 can only cover the second surface 13, and can also exceed the second surface 13 to cover parts or all of the first surface 12 or the third surface 14. The conductor layer 8 is formed on the insulator layer 7, where the conductor layer 8 can be only formed on a certain area upon the insulator layer 7 corresponding to the second surface 13. On the other hand, the conductor layer 8 also can exceed the certain area upon the insulator layer 7 corresponding to the second surface 13 to cover parts or all of the insulator layer 7 corresponding to the first surface 12 or the third surface 14.

Through the combination of the above-mentioned embodiments, the laser semiconductor can be achieved to emit UV light, visible light or infrared light.

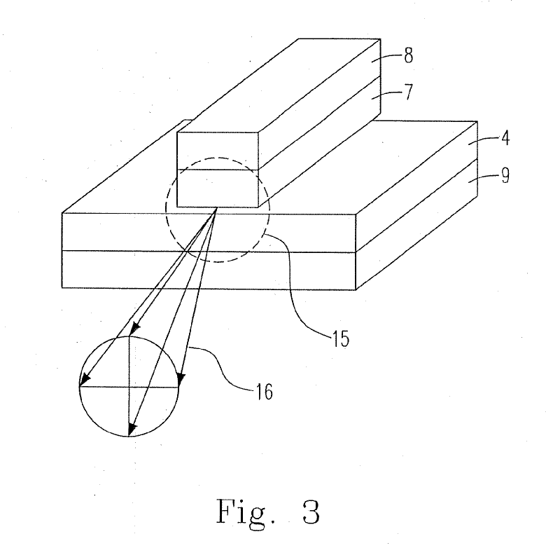

Please refer to FIG. 3, which is a schematic diagram showing the laser apparatus emitting lights according to a third preferred embodiment of the present invention. The laser apparatus according to the third preferred embodiment of the present invention provided herein only contains a semiconductor layer 4, an insulator layer 7, conductor layers 8 and 9, and a laser cavity 15 formed by the mentioned layers. This laser apparatus further contains a first electrode and a second electrode (not shown in FIG. 3) connected to the conductor layer 8 and the conductor layer 9 respectively, and the laser apparatus emits a laser beam 16 through the laser cavity 15.

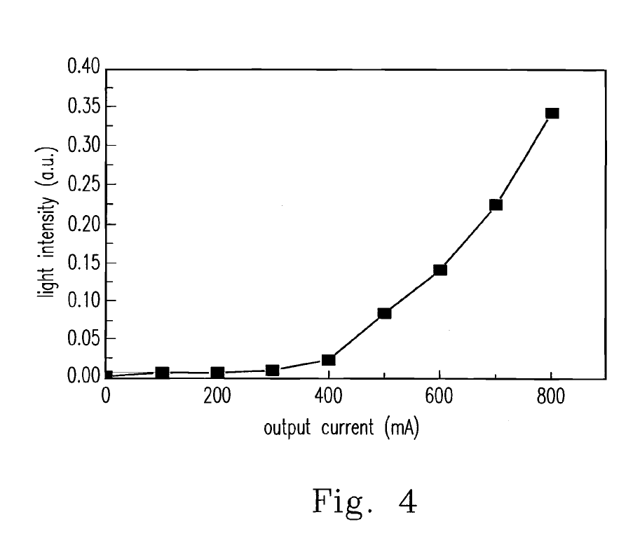

Please refer to FIG. 4, which is a broken-line graph showing the light intensity of the laser apparatus of the present invention after a current is input thereto, where the ratio of the light intensity to the current input is shown therein.

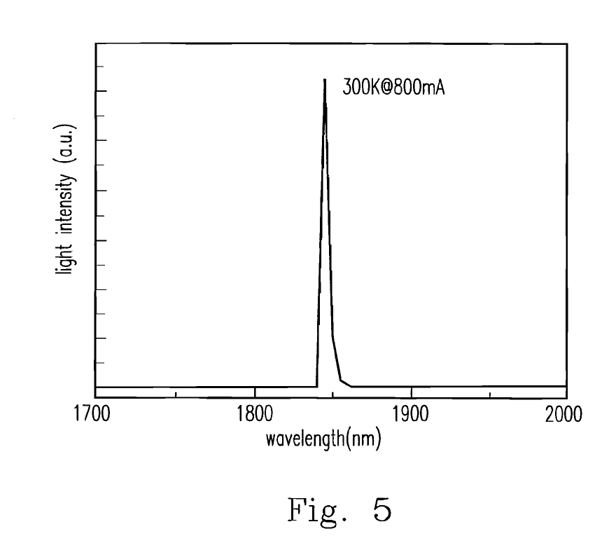

Please refer to FIG. 5, which is a broken-line graph showing the light characteristic of the laser apparatus of the present invention when the temperature is 300K and the input current is 800 mA, wherein the x-axis indicates the wavelength, and the y-axis indicates the light intensity. It is shown that the laser apparatus of the present invention generates a very strong infrared laser with a wavelength of about 1850 nm. Other types of lasers, such as a UV laser and a visible light laser, can be generated by different combinations of the above-mentioned components.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A laser apparatus comprising:
at least one semiconductor layer having a first surface and a second surface; and
an insulator layer formed on the first surface of the at least one semiconductor layer, wherein the at least one semiconductor layer and the insulator form a laser cavity.

2. A laser apparatus according to claim 1 further comprising a conductor layer formed on one of the insulator layer and the second surface of the at least one semiconductor layer.

3. A laser apparatus according to claim 2, wherein the conductor layer is made of a material selected from a group consisting of a metal, an alloy and a relative heavily doped III-V semiconductor.

4. A laser apparatus according to claim 3, wherein the metal is selected from a group consisting of an aluminum, a platinum, and a gold, and the relative heavily doped III-V semiconductor is one of a P type semiconductor and an N type semiconductor.

5. A laser apparatus according to claim 3, wherein the metal is selected from a group consisting of an aluminum, a platinum, and a gold, and the relative heavily doped III-V semiconductor is one of a binary compound and a multi-element compound.

6. A laser apparatus according to claim 1 further comprising a substrate mounted under the second surface of the at least one semiconductor layer, wherein the at least one semiconductor layer is formed upon the substrate by an epitaxy technique.

7. A laser apparatus according to claim 6, wherein the substrate is one selected from a group consisting of a semiconductor substrate, a crystal substrate, a glass substrate, a plastic substrate and a combination thereof.

8. A laser apparatus according to claim 7, wherein the semiconductor substrate is one selected from a group consisting of a silicon substrate, a germanium substrate and a combination thereof, and the crystal substrate has a crystal orientation being one selected from a group consisting of {100}, {110} and {111}.

9. A laser apparatus according to claim 6 further comprising a conductor formed under the substrate.

10. A laser apparatus according to claim 1, wherein the first surface comprises a third surface, a fourth surface and a fifth surface located between the third surface and the fourth surface, and the insulator layer is formed upon the fifth surface.

11. A laser apparatus according to claim 10, wherein the fifth surface is configured higher than the third surface and the fourth surface.

12. A laser apparatus according to claim 1, wherein the at least one semiconductor layer is one selected from a group consisting of a silicon, a germanium, a IV semiconductor, a III-V semiconductor and a II-VI semiconductor.

13. A laser apparatus according to claim 1, wherein the at least one semiconductor layer further comprises one selected from a group consisting of a buffer layer, a hollow layer and a combination thereof, and the laser cavity comprises at least one natural fracture surface fracturing along a crystal structure of the layers.

14. A laser apparatus according to claim 1, wherein the at least one semiconductor layer is a regional doped semiconductor being doped in layers or doped with gradually varying concentrations, and the laser cavity is in a shape of one of a bar and a disk.

15. A laser apparatus according to claim 1, wherein the at least one semiconductor layer further comprises at least one selected from a group consisting of at least a quantum dot, at least a quantum line, at least a quantum well, and a combination thereof, and the insulator layer is made of a material selected from a group consisting of a silicon oxide, an aluminum oxide, a silicon nitride, a hafnium oxide and a combination thereof.

16. A manufacturing method for a laser apparatus, comprising steps of:
(a) providing at least one semiconductor layer;
(b) forming an insulator layer on the at least one semiconductor layer; and
(c) forming a laser cavity in the at least one semiconductor layer and the insulator layer.

17. A manufacturing method according to claim 16 further comprising a step of forming a conductor layer upon the insulator layer.

18. A manufacturing method according to claim 16 further comprising steps of:
forming a conductor layer under the at least one semiconductor layer; and
configuring a substrate between the at least one semiconductor layer and the conductor layer, wherein the at least one semiconductor layer is formed upon the substrate by an epitaxy technique.

19. A manufacturing method according to claim 16 further comprising a step of providing a substrate, wherein the at least one semiconductor layer is formed upon the substrate.

20. A manufacturing method according to claim 16 further comprising a step of forming the laser cavity by one selected from a group consisting of a lithography and etching technique, a lapping and polish technique, a thin film coating technique, splitting along a crystal structure of the layers, and a combination thereof, wherein the at least one semiconductor layer comprises a first surface, a third surface and a second surface located between the first surface and the third surface, the insulator layer is formed only upon the second surface in the step (b), and the second surface is higher than the first surface and the third surface.
